(19) United States
(12) Patent Application Publication
(10) Pub. No.: US 2007/0113136 A1
(43) Pub. Date: May 17, 2007

(54) Detection rate calculation method of test pattern, recording medium, and detection rate calculation apparatus of test pattern

(75) Inventor: Yukinori Nakajima, Kashihara (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 11/585,910

(22) Filed: Oct. 25, 2006

(30) Foreign Application Priority Data
Oct. 25, 2005 (JP) 2005-310293

(51) Int. Cl. G01R 31/28; G06F 11/00

(52) U.S. Cl. 714/738

(57) ABSTRACT

To provide a detection rate calculation method of a test pattern for calculating how much a test pattern can detect short-out generated between the adjacent lines in an integrated circuit. A layout creating program 12 creates layout data 25 from circuit data 21, and creates the information of the adjacent lines from layout data 25 as the adjacent line information 24. A transistor level simulation program 11 executes simulation by using a test pattern 22 and creates a potential of each line in the circuit as the potential information 23. A fault detection rate calculation program 13 checks if a potential difference between the adjacent lines is not less than a predetermined potential difference or not from the adjacent line information 24 and the potential information 23 and calculates a detection rate of short-out.

### CROSS-REFERENCE OF RELATED APPLICATION

This Nonprovisional Application claims priority under 35 U.S.C. §119(a) on Patent Application No. 2005-310293 in Japan on Oct. 25, 2005, the entire contents of which are hereby incorporated by reference.

### BACKGROUND OF THE INVENTION

1. Field of the Invention

The present invention relates to a detection rate calculation method of a test pattern that a test pattern for testing a semiconductor integrated circuit calculates an efficiency to detect a break in a circuit as a detection rate, a recording medium of storing a computer program that causes a computer to practice this detection rate calculation method, and a detection rate calculation apparatus of a test pattern that practices this detection rate calculation method.

2. Description of the Related Art

Semiconductor integrated circuits are discriminated into a good-quality product and a defective product in a test step after a creating step has been completed and only the good-quality product is shipped as a product. Thereby, a quality of a product is improved. In the test step, a voltage property test to test a property such as an input voltage value and an output voltage value, a current property test to test a property such as a leak current for each input and output terminal and a consumption current upon operation, a timing property test to test a setup/hold time and an operational frequency or the like, and a function test to test a function when a semiconductor integrated circuit is operated or the like are done by a test apparatus.

It is necessary for a designer or a test designer of a semiconductor integrated circuit to create a test pattern such as an input voltage pattern data, which is carried out by a test apparatus, in order to do a test of the semiconductor integrated circuit. In the case that the test pattern is not designed optimally, it is feared that a product malfunctions after shipment or the product is not operated after shipment or the like. Since it is feared that the malfunction of the semiconductor integrated circuit involves human lives when the semiconductor integrated circuit shipped as a product is used for an apparatus for vehicle installation or for a medicine purpose, a high quality is required from the semiconductor integrated circuit to be shipped. Therefore, it is necessary to do a test, which can distinguish a good-quality product and a defective product more reliably.

In recent years, in order to more improve the quality of the semiconductor integrated circuit, a scan test and an IDDQ (a rest current) test or the like are introduced. The scan test is one kind of a function test, and by incorporating a circuit for a test to connect flip flops in the semiconductor integrated circuit in a line like a shift resistor in advance, inputting the data in a row of the flip flop sequentially and comparing the data with an expected value of the output, it is possible to examine the operation of a flip flop in the semiconductor integrated circuit and a logic circuit between the flip flops or the like. The IDDQ test operates the semiconductor integrated circuit inputting the test pattern of the function test including the scan test and stops the operation stopping the input of the test pattern temporarily in the middle of the operation so as to measure the current flowing through a power supply terminal with the operation being stopped. According to the IDDQ test, it is possible to examine if a fault of a transistor connected to a power line in the semiconductor integrated circuit and a fault due to short cut of the power line and other lines or the like occur or not.

In addition, a program or an apparatus or the like, which can calculate a rate capable of detecting faults of the transistor and the line or the like to configure the semiconductor integrated circuit as a detection rate, has been put into practical use. As the detection rate of the function test, for example, the fault detection rate that each line in the semiconductor integrated circuit shorts out to the power line or a GND (a ground), a so-called the detection rate of stuck-at fault is used. In addition, according to the IDDQ test, for example, a rate of the number of the line changed from “High→Low→High” or “Low→High→Low” is calculated as a toggle rate and the toggle rate is defined as a fault detection rate. Thereby, the designer can create a test pattern having a higher detection rate.

As one of faults occurring in the semiconductor integrated circuit, a fault such that the adjacent lines short out each other is considered. For example, this fault can be detected by the IDDQ test because a current flow from one line to other line when an electric potential of one of shorted-out line becomes “High” and that of other line becomes “Low”. However, the toggle rate calculated as the detection rate of the IDDQ test does not consider a potential difference between the adjacent lines, so that the toggle rate cannot be used as the detection rate of the fault due to short circuit of the adjacent lines.

In Japanese Patent Application Laid-Open No.06-194418, an LSI test data generation apparatus, which converts the input signal of the semiconductor integrated circuit into the input data of a tester and converts the output signal data into a expected value data of the tester when a gate level simulation of the semiconductor integrated circuit is carried out and it is determined that signal values of the adjacent lines are different from each other, has been suggested. In addition, an LSI test data generation apparatus, which sets signal values different from each other for the adjacent lines, obtains the input signal data following the logic of the circuit to the input side and converts it into the input data of the tester so that the input signal takes the set signal value, and obtains the logic of the circuit from the set signal value following the logic of the circuit to the output side and converts it into the output data of the tester, has been suggested.

### BRIEF SUMMARY OF THE INVENTION

However, according to an LSI test data generation apparatus described in Japanese Patent Application Laid-Open No.06-194418, in the case of converting from the input signal data into the input data of the tester, an input pattern to meet a requirement is extracted from the input signal data prepared in advance. Therefore, this involves a problem such that the fault of the short circuit of the adjacent lines each other cannot detected if a pattern to make the signal values of the adjacent lines into the different values is not included in the input signal data prepared in advance.

In the case of obtaining the input signal data following the logical of the circuit from the set signal value, the larger the size of the circuit of the semiconductor integrated circuit is, the more it is difficult to follow the logic of the circuit. Further, there may be no input signal data corresponding to the set signal value. In addition, even in the case that no input signal data can be obtained, the data amount becomes very large, so that it is feared that the designer should contract the input signal data in consideration of a test time. The contraction of the input signal data is a difficult work and due to the contraction, it is feared that a fault cannot be detected.

In addition, short-out of the adjacent lines is not generated only between the lines to connect gate elements such as a NAND or a NOR but there is a possibility that short-out of the adjacent lines occurs between the lines to connect a plurality of transistors configuring the gate element. However, the LSI test data generation apparatus described in the patent document 1 determines if the signal values of the adjacent lines are different from each other depending on a result of a gate level simulation. As a result, this involves a problem such that the short-out of the line within the gate element cannot be detected. In addition, the semiconductor integrated circuit having a digital circuit and an analog circuit mixed therein cannot carry out simulation, and this involves a problem such that short-cut of the line for a digital signal and the line for an analog signal cannot be detected.

The present invention has been made taking the foregoing problems into consideration and an object of which is to provide a detection rate calculation method of a test pattern for calculating a detection rate of a fault of an integrated circuit detected by a test pattern in which an input voltage pattern data for testing the integrated circuit is set, the method comprising steps of: extracting, based on arrangement information with respect to wires of the integrated circuit, combinations of a pair of adjacent wires; calculating a potential of each wire when the test pattern is inputted in the integrated circuit; determining whether or not a potential difference between each combination of a pair of the adjacent wires is larger than a predetermined potential difference; and calculating the detection rate in accordance with a determination result on the potential difference.

In addition, other object of the present invention is to provide a detection rate calculation method of a test pattern further comprising a step of obtaining information with respect to timing for determining on the potential difference, wherein determination on the potential difference is carried out at the timing in the test pattern.

In addition, other object of the present invention is to provide a detection rate calculation method of a test pattern wherein, in the step of calculating the detection rate, in accordance with the determination result on the potential difference, it is determined whether or not the fault of the integrated circuit is detected, and in accordance with a determination result on the fault of the integrated circuit, the detection rate is calculated.

In addition, other object of the present invention is to provide a memory product which is readable by a computer and stores a computer program causing the computer to calculate a detection rate of a fault of an integrated circuit detected by a test pattern in which an input voltage pattern data for testing the integrated circuit is set, the computer program comprising steps of: causing the computer to determine whether or not a potential difference between a combination of a pair of adjacent wires of the integrated circuit is larger than a predetermined potential difference; and causing the computer to calculate the detection rate in accordance with a determination result on the potential difference.

Further, other object of the present invention is to provide the memory product, wherein the computer program further comprises a step of causing the computer to obtain information with respect to the predetermined potential difference, and in the step of causing the computer to determine, the determination is carried out in accordance with the obtained information.

In addition, other object of the present invention is to provide the memory product, wherein the computer program further comprises a step of causing the computer to obtain information with respect to timing for determining on the potential difference, and in the step of causing the computer to determine, the determination is carried out at the timing in the test pattern.

Further, other object of the present invention is to provide the memory product, wherein, in the step of causing the computer to calculate the detection rate, in accordance with the determination result on the potential difference, it is determined whether or not the fault of the integrated circuit is detected; and in accordance with a determination result on the fault of the integrated circuit, the detection rate is calculated.

In addition, other object of the present invention is to provide the memory product, wherein, in the step of causing the computer to calculate the detection rate, a rate of an accumulated number of each combination of a pair of adjacent wires, between each combination of which potential difference is determined to be larger than a predetermined potential difference, with respect to a totally accumulated number of each combination of a pair of adjacent lines is calculated as the detection rate.

Further, other object of the present invention is to provide the memory product, wherein the computer program further comprises a step of causing the computer, on the basis of the determination result on the potential difference, to create display data to display the determination result with emphasis on a position of each wire in accordance with arrangement information with respect to wires, whereby the designer can determine the line of which fault cannot be detected more reliably.

In addition, other object of the present invention is to provide a detection rate calculation apparatus of a test pattern for calculating a detection rate of a fault of an integrated circuit detected by a test pattern in which an input voltage pattern data for testing the integrated circuit is set, comprising a controller capable of performing operations of: determining whether or not a potential difference between a combination of a pair of adjacent wires of the integrated circuit is larger than a predetermined potential difference; and calculating the detection rate in accordance with a result of determination on the potential difference.

Further, other object of the present invention is to provide a detection rate calculation apparatus of a test pattern, wherein the controller is further capable of performing an operation of obtaining information with respect to timing for determining on the potential difference, and in the operation of determining on the potential difference, the determination is carried out at the timing in the test pattern.

Further, other object of the present invention is to provide a detection rate calculation apparatus of a test pattern, wherein, in the operation of calculating the detection rate, a rate of an accumulated number of each combination of a pair of adjacent wires, between each combination of which potential difference is determined to be larger than a predetermined potential difference, with respect to a totally accumulated number of each combination of a pair of adjacent wires is calculated as the detection rate.

In addition, other object of the present invention is to provide a detection rate calculation apparatus of a test pattern, wherein the controller is further capable of performing operations of: obtaining arrangement information with respect to wires of the integrated circuit; and creating display data, based on the determination result, to display the determination result with emphasis on a position of each wire in accordance with the arrangement information, and the display part displays an image on the basis of the data for display.

Further, other object of the present invention is to provide a detection rate calculation apparatus of a test pattern, wherein the controller is further capable of performing operations of: executing a transistor level simulation of the integrated circuit; and obtaining information with respect to a potential of each wire.

A detection rate calculation method of a test pattern according to the present invention may comprise a detection rate calculation method of a test pattern for calculating a detection rate of a fault of an integrated circuit detected by a test pattern, in which an input voltage pattern data for testing the integrated circuit is set, the method comprising steps of extracting combinations of a pair of the adjacent lines from the arrangement information with respect to the line of the integrated circuit; calculating a potential of each line when the test pattern is inputted in the integrated circuit; determining if the potential difference between the pair of the adjacent lines is larger than a predetermined potential difference or not on the basis of the calculated potential of each line; and calculating the detection rate in accordance with a result of determination.

According to the present invention, extracting the adjacent lines from the arrangement information of the semiconductor integrated circuit, it is determined if a potential difference between the adjacent lines is larger than a predetermine potential or not. When a potential difference occurs between the adjacent lines, if the adjacent lines are shorted out, a current flows from the line having a higher potential into the line having a lower potential. Therefore, by doing the IDDQ test, the fault can be detected. Therefore, determining the potential difference between the adjacent lines, a detection rate of the fault with respect to short-out of the line can be calculated from a determination result.

In addition, the detection rate calculation method of a test pattern according to the present invention may further comprise a step of obtaining the information with respect to timing for determining the potential difference between the pair of the adjacent lines, wherein determination of the potential difference between the pair of the adjacent lines is carried out at the timing in the test pattern.

According to the present invention, obtaining a determination timing to be set by the designer, the determination of the potential difference between the adjacent lines is carried out at the obtained timing in the test pattern. In the case of doing the IDDQ test, inputting the test patterns are sequentially in the semiconductor integrated circuit and temporarily stopping the input of the test pattern at a predetermined timing of several to several tens of places in the test pattern, the current flowing through the power supply in this time is measured. By measuring the potential difference between the lines in accordance with a timing of the current measurement of the IDDQ test, it is possible to calculate a more accurate detection rate of the fault.

In addition, in the detection rate calculation method of a test pattern according to the present invention, in the step of calculating the detection rate, a rate of the number of sets of a pair of the adjacent lines, of which potential difference is determined to be larger than a predetermined potential difference, with respect to the total number of sets of a pair of the adjacent lines is calculated as the detection rate.

According to the present invention, making the set of the adjacent lines of which potential difference is larger than a predetermined potential difference into a set of lines capable of detecting a fault, a rate that this set of lining occupies the all sets of adjacent lines is made into a detection rate of the fault. Since a complicated calculation is not required for calculation of the detection rate, the calculation of the detection rate can be carried out at a high speed.

In addition, a recording medium according to the present invention comprise a recording medium readable by a computer of storing a computer program causing the computer to calculate the detection rate of the fault of an integrated circuit, which is detected from a test pattern having an input voltage pattern data for examining the integrated circuit set therein, the computer program comprising steps of: causing the computer to determine if the potential difference between the pair of the adjacent lines of the integrated circuit is larger than a predetermined potential difference or not; and causing the computer to calculate the detection rate in accordance with the determination result.

According to the present invention, obtaining the information of the adjacent lines in the semiconductor integrated circuit and obtaining the information of a potential of each line when the test pattern is inputted and operated, it is determined if a potential difference between the adjacent lines is larger than a predetermined potential difference or not. When a potential difference occurs between the adjacent lines, since the fault of short-out of the line can be detected by doing the IDDQ test, determining the potential difference between the adjacent lines, the detection rate of the fault with respect to short-out of the line can be calculated from the determination result.

In addition, in the recording medium according to the present invention, the computer program further comprises a step of causing the computer to obtain the information with respect to the predetermined potential difference; and, in the step of causing the computer to carry out determination, the determination is carried out in accordance with the obtained information.

According to the present invention, obtaining a predetermined potential difference, which is a determination reference, the determination of the potential difference is carried out on the basis of the obtained potential difference. In the case of the semiconductor integrated circuit having a digital circuit and an analog circuit mixed, there is a line for an analog signal, which is a potential other than a power supply potential and a GND potential. When such lines are aligned being mixed, even if the potential difference occurs between the lines, there is a possibility that the potential difference is minute. Then, when the potential difference is minute, since the current amount of the flowing current is minute, there is a possibility that a test apparatus cannot detect it. Therefore, an appropriate determination reference is determined in accordance with a circuit configuration and a capability of the test apparatus or the like by the designer and it is possible to calculate a more reliable detection rate obtaining this potential difference.

Further, in the recording medium according to the present invention, the computer program further comprises a step of causing the computer to obtain the information with respect to timing for determining the potential difference between the pair of the adjacent lines; an, in the step of causing the computer to carry out determination, the determination is carried out at the timing in a test pattern.

According to the present invention, obtaining the timing information to be set by the designer, the potential difference between the lines is determined at the obtained timing in the test pattern. Since the potential difference between the lines can be determined in accordance with the timing of the current measurement of the IDDQ test, the more accurate detection rate of the fault can be calculated.

In addition, in the recording medium according to the present invention, in the step of causing the computer to calculate the detection rate, a rate of the number of sets of a pair of the adjacent lines, of which potential difference is determined to be larger than a predetermined potential difference, with respect to the total number of sets of a pair of the adjacent lines is calculated as the detection rate.

According to the present invention, making the set of the adjacent lines of which potential difference is larger than a predetermined potential difference into a set of lines capable of detecting a fault, a rate that this set of lining occupies the all sets of adjacent lines is made into a detection rate of the fault. Since the method of calculating the detection rate is simple, it is possible to carry out the processing of a computer program at a high speed.

Further, in the recording medium according to the present invention, the computer program further comprises a step of causing the computer to create data for display to display the determination result with emphasis on a position of each line in accordance with the arrangement information with respect to the line on the basis of the determination result in the step of causing the computer to carry out determination.

According to the present invention, obtaining the arrangement information of a semiconductor integrated circuit, data for display is created, which displays the lines of which potential lines between the lines is larger than a predetermined potential line or is not larger than a predetermined potential line, on the basis of the arrangement information with emphasis. Displaying the created data for display by an apparatus for displaying the created data for display or a program or the like, the designer can easily discriminate the line capable of detecting the fault and the line not capable of detecting the fault.

In addition, in the recording medium according to the present invention, in the step of causing the computer to create data for display for displaying the determination result with emphasis, in accordance with the determination result, a color mark is set at a position of each line.

According to the present invention, the data for display to display the lines by color coding with colors with emphasis in accordance with the determination result of the potential difference between the adjacent lines is created. For example, the line of which fault can be detected by blue and the line of which fault can be detected by red so that the line that the designer can detect the fault and the line that the designer cannot detect the fault can be visually discriminated.

Further, a detection rate calculation apparatus of a test pattern according to the present invention may comprise a detection rate calculation apparatus of a test pattern for calculating a detection rate of a fault of an integrated circuit detected by a test pattern, in which an input voltage pattern data for testing the integrated circuit is set, comprising a controller capable of performing operations of determining if the potential difference between the pair of the adjacent lines of the integrated circuit is larger than a predetermined potential difference or not; and calculating the detection rate in accordance with a result of determination.

According to the present invention, obtaining the arrangement information of the adjacent lines of the semiconductor integrated circuit and obtaining the information of a potential of each line when the test pattern is inputted and operated, the designer determines if the potential difference between the adjacent lines is larger than a predetermined potential or not. When the potential difference occurs between the adjacent lines, since the fault of short-cut of the line can be detected by doing the IDDQ test, determining the potential difference between the adjacent lines, the detection rate of the fault with respect to short-cut of the line can be calculated from the determination result.

In addition, in the detection rate calculation apparatus of a test pattern according to the present invention, the controller is further capable of performing an operation of obtaining the information with respect to timing for determining the potential difference between the pair of the adjacent lines, and in the operation of determining if the potential difference between the pair of the adjacent lines is larger than a predetermined potential difference, determination is carried out at the timing in the test pattern.

According to the present invention, obtaining the timing information to be set by the designer, the designer determines the potential difference between the adjacent lines at the obtained timing in the test pattern. Since the determination of the potential difference can be made in accordance with the timing of the current measurement of the IDDQ test, a more accurate detection rate of the fault can be calculated.

Further, in the detection rate calculation apparatus of a test pattern according to the present invention, in operation of calculating the detection rate, a rate of the number of sets of a pair of the adjacent lines, of which potential difference is determined to be larger than a predetermined potential difference, with respect to the total number of sets of a pair of the adjacent lines is calculated as the detection rate.

According to the present invention, by making the set of the adjacent lines of which potential difference is larger than a predetermined potential difference into a set of lines capable of detecting a fault, a rate that this set of lining occupies the all sets of adjacent lines is made into a detection rate of the fault. Since the method of calculating the detection rate is simple, the processing time can be shortened.

In addition, in the detection rate calculation apparatus of a test pattern according to the present invention, the controller is further capable of performing operations of: obtaining the arrangement information with respect to the line of the integrated circuit; and creating data for display for displaying the determination result with emphasis on the arrangement position in accordance with the arrangement information of each line on the basis of the determination result; and the display part displays an image on the basis of the data for display.

According to the present invention, obtaining the arrangement information of a semiconductor integrated circuit, data for display is created, which displays the lines of which potential lines between the lines is larger than a predetermined potential line or is not larger than a predetermined potential line, on the basis of the arrangement information with emphasis. Then, the created data for display is displayed to the designer. Thereby, the designer can easily discriminate the line capable of detecting the fault in the circuit and the line not capable of detecting the fault in the circuit.

Further, in the detection rate calculation apparatus of a test pattern according to the present invention, the controller is further capable of performing operations of: executing a transistor level simulation of the integrated circuit; and obtaining the information with respect to a potential of each line.

According to the present invention, by executing at transistor level simulation of the semiconductor integrated circuit, the information with respect to the potential of each line is obtained. Thereby, it is determined that the fault of short-out can be detected or not with respect to the line to connect a plurality of transistors configuring a gate element such as a NAND and a NOR. In addition, even in the case that the digital circuit and the analog circuit are mixed and the lines for the analog signal to be a potential other than the power supply potential and the GND potential are located adjacently, the detection rate of the fault can be calculated.

According to the present invention, when the test pattern is executed, by determining if a potential difference between the adjacent lines is larger than a predetermined potential difference or not and calculating a fault detection rate from a determination result, it is possible to present how much a test pattern created by a designer can detect a fault of short-out between the adjacent lines to a designer, so that the designer can add, delete, or correct the test pattern on the basis of the detection rate. Thereby, since the test pattern capable of reliably detecting the fault of short-out between the lines of a semiconductor integrated circuit can be created, it is possible to reliably discriminate a good-quality product and a defective product in the test step and this makes it possible to improve a quality of a product to be shipped.

In addition, according to the present invention, obtaining a timing of determination be set by the designer and determining the potential difference between the adjacent lines at the obtained timing in the test pattern, the potential difference between the lines can be determined in accordance with the timing of the current measurement of the IDDQ test and the more accurate detection rate of the fault can be calculated. Therefore, the designer can more manufacture the test pattern capable of reliably detecting the fault of short-out between the lines, it is possible to reliably discriminate a good-quality product and a defective product in the test step, and this makes it possible to improve a quality of a product to be shipped.

Further, according to the present invention, since a complicated calculation is not required for calculation of the detection rate and the calculation of the detection rate can be carried out at a high speed by calculating a rate of the number of set of the adjacent lines, of which potential difference is determined to be larger than a predetermined potential difference, against the total number of sets of the adjacent lines, the processing time can be shortened and a time till the designer obtains the calculation result can be shortened.

In addition, according to the present invention, it is possible to present how much a test pattern created by a designer can detect a fault of short-out between the adjacent lines to a designer by obtaining the information of the adjacent lines in the semiconductor integrated circuit, obtaining the potential information of each line when a test pattern is executed, determining if a potential difference between the adjacent lines is larger than a predetermined potential difference or not when the test patter is executed on the basis of the obtained information, and calculating a detection rate of the fault from a determination result. Therefore, the designer can add, delete, or correct the test pattern on the basis of the detection rate. Thereby, since the test pattern capable of reliably detecting the fault of short-out between the lines of a semiconductor integrated circuit can be created, it is possible to reliably discriminate a good-quality product and a defective product in the test step and this makes it possible to improve a quality of a product to be shipped.

Further, according to the present invention, obtaining a predetermined potential difference, which is a determination reference, and carrying out determination using the obtained potential difference, even in the case that the digital circuit and the analog circuit are mixed and the lines for the analog signal to be a potential other than the power supply potential and the GND potential are located, the designer can carry out appropriate determination in accordance with the potential difference of the determined determination reference by determining an appropriate determination reference in accordance with the circuit structure and a capability of the test apparatus or the like by the designer. Therefore, it is possible to create the test pattern capable of reliably detecting the fault of short-out between the lines of the semiconductor integrated circuit and this makes it possible to improve a quality of a product to be shipped.

In addition, according to the present invention, by obtaining the timing information to be set by the designer and carrying out determination at the obtained timing in the test pattern, determination of the potential difference between the lines can be carried out in accordance with the timing of the current measurement of the IDDQ test, and the more accurate detection rate of the fault can be calculated. As a result, the designer can create the test pattern which can reliably detect the fault of short-out between the lines, it is possible to reliably discriminate a good-quality product and a defective product in the test step, and this makes it possible to improve a quality of a product to be shipped.

Further, according to the present invention, a complicated calculation is not required for calculation of the detection rate and the calculation of the detection rate can be carried out at a high speed by making the set of the adjacent lines of which potential difference is larger than a predetermined potential difference into a set of lines capable of detecting a fault and making a rate that this set of lining occupies the all sets of adjacent lines into a detection rate of the fault. Therefore, a response of a computer program can be shortened and a convenience for the designer can be improved.

Further, according to the present invention, by obtaining the arrangement information of the semiconductor integrated circuit, creating display data to display a determination result if a potential difference between the lines is larger than a predetermined potential or not with emphasis in the arrangement information, and displaying the created display data by means of an apparatus or a program or the like for display, the designer can easily discriminate the line of which fault can be detected and the line of which fault cannot be detected. As a result, the designer can create the test pattern which can detect the fault of short-out between the lines more reliably and a quality of a product to be shipped can be improved. In addition, it is possible to improve a convenience for the computer program which calculates the detection rate of the fault.

Further, according to the present invention, since the designer can reliably discriminate the wire of which fault cannot be detected by displaying the lines by color coding with colors with emphasis in accordance with the determination result, the designer can create the test pattern which can detect the fault of the short-out between the line more reliably and a quality of a product to be shipped can be improved. In addition, it is possible to further improve a convenience of a computer program for calculating a fault detection rate.

Further, according to the present invention, the designer can create a test pattern which can reliably detect the fault of short-out between the lines of the semiconductor integrated circuit by obtaining the information of the adjacent lines in the semiconductor integrated circuit, obtaining the potential information of each line when a test pattern is executed, determining if a potential difference between the adjacent lines is larger than a predetermined potential difference or not when the test patter is executed on the basis of the obtained information, and calculating a detection rate of the fault from a determination result. Therefore, it is possible to reliably discriminate a good-quality product and a defective product in the test step and this makes it possible to improve a quality of a product to be shipped.

In addition, according to the present invention, by obtaining the timing information set by the designer and carrying out determination at the obtained timing in the test pattern, determination can be carried out at a timing of a current measurement of the IDDQ test. As a result, it is possible to create a test pattern which can calculate a more accurate detection rate of the fault and whereby the designer can reliably detect the fault of short-out between the lines. Therefore, a quality of a product to be shipped can be improved.

In addition, according to the present invention, a complicated calculation is not required for calculation of the detection rate and the calculation of the detection rate can be carried out at a high speed by making the set of the adjacent lines of which potential difference is larger than a predetermined potential difference into a set of lines capable of detecting a fault and making a rate that this set of lining occupies the all sets of adjacent lines into a detection rate of the fault. Therefore, the processing time of a detection rate calculation apparatus of a test pattern and a convenience for the designer can be improved.

Further, according to the present invention, it is possible to present the line of which fault cannot be detected to a designer with emphasis and the designer can discriminate the line of which fault cannot be easily detected by obtaining the arrangement information of a semiconductor integrated circuit, creating display data to display a determination result if a potential difference between the lines is larger than a predetermined potential or not with emphasis in the arrangement information, and displaying the created display data, so that the designer can discriminate the line of which fault cannot be easily detected. As a result, the designer can create a test pattern which can reliably detect the fault of short-out between the line and a quality of the product to be shipped can be improved. In addition, a convenience for a detection rate calculation apparatus of a test pattern can be improved.

Further, according to the present invention, by executing a transistor level simulation of the semiconductor integrated circuit and obtaining the potential of each line from a simulation result, a detection rate for the fault due to short-out can be calculated with respect to the line to connect a plurality of transistors configuring the gate terminal such as a NAND or a NOR. Further, even in the case that the digital circuit and the analog circuit are mixed and the lines for the analog signal to be a potential other than the power supply potential and the GND potential are located adjacently, the detection rate of the fault can be calculated. Therefore, it is possible to more reliably discriminate a good-quality product and a defective product in the test step and this makes it possible to improve a quality of a product to be shipped.

The above and further objects and features of the invention will more fully be apparent from the following detailed description with accompanying drawings.

### BRIEF DESCRIPTION OF THE SEVERAL VIEWS OF THE DRAWINGS

FIG. 1 is a block diagram showing a structure of a computer as a detection rate calculation apparatus of a test pattern according to the present invention;

FIG. 2 is a pattern diagram showing a mutual relation between a program and data, which are recorded in a hard disk;

FIG. 3 is a circuit diagram showing a circuit example of a semiconductor integrated circuit;

FIG. 4 is a pattern diagram showing a layout example of the semiconductor integrated circuit;

FIG. 5 is a waveform view showing a potential of each line when a test pattern is inputted in the semiconductor integrated circuit;

FIG. 6 is a waveform view showing a potential difference between the adjacent lines when the test pattern is inputted in the semiconductor integrated circuit;

FIG. 7 is a chart showing a determination result showing if a fault due to short-out of the adjacent lines of the semiconductor integrated circuit can be detected or not according to the present invention;

FIG. 8 is a flow chart showing a processing order of a program for calculating a fault detection rate according to the present invention;

FIG. 9 is a flow chart showing a processing order of the fault detection rate according to the present invention; and

FIG. 10 is a pattern view showing an emphasis display example of the layout of the semiconductor integrated circuit.

### DETAILED DESCRIPTION OF THE INVENTION

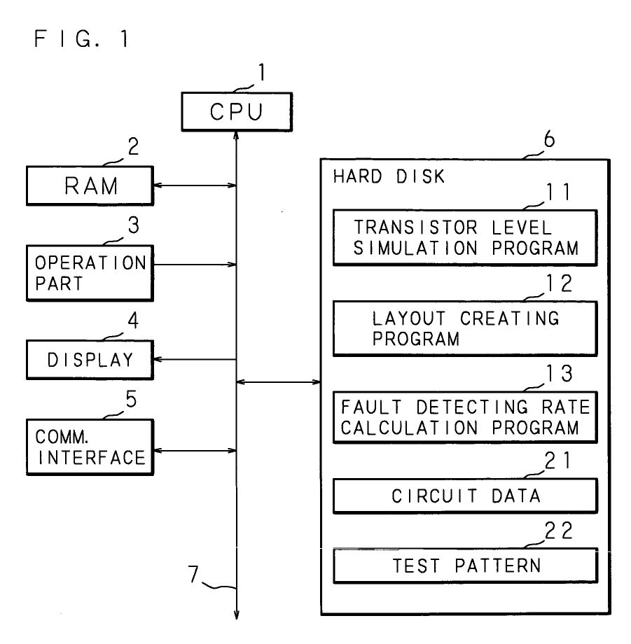

Hereinafter, the present invention will be specifically described with reference to the drawings illustrating the embodiment. FIG. 1 is a block diagram showing a structure of a computer as a detection rate calculation apparatus of a test pattern according to the present invention. In FIG. 1, a reference numeral 1 denotes a CPU of a computer and it may carry out arithmetic processing and may control each part in the computer. To the CPU 1, a RAM 2, an operation part 3, a display part 4, a communication interface 5, and a hard disk 6 or the like are connected each other via a bus 7.

The RAM 2 is configured by a SRAM and a DRAM or the like, and various programs and data or the like recorded in the hard disk 6 are read to the RAM 2 to be executed or processed by the CPU 1. The operation part 3 is provided with an input device such as a key board and a mouse or the like, and accepting the operation to be carried out by a designer, it may give the operational content to the CPU 1. The display part 4 is provided with a liquid crystal display or a CRT display or the like and the processing result of the CPU 1 is displayed thereon. For example, a circuit diagram, a layout, and simulation of a semiconductor integrated circuit or the like are displayed. The communication interface 5 is provided with a connector to which a communication cable of a LAN is connected to send and receive the data to and from other computer via the communication cable.

In the hard disk 6, as a software program necessary for development of design of the semiconductor integrated circuit, a transistor level simulation program 11, a layout creating program 12, and a fault detection rate calculation program 13 are recorded. In addition, in the hard disk 6, circuit data 21 of the semiconductor integrated circuit which is designed by the designer and a test pattern 22 of the semiconductor integrated circuit or the like are recorded. The circuit data 21 is a text file of a so-called net list format, and this data is formed by means of directly describing the data by the designer; inputting a circuit diagram in a circuit diagram input program as a net list; or logically synthesizing a digital circuit which is described by a RTL (Register Transfer Level) and outputting it or the like. The test pattern 22 on which an input voltage pattern data or the like is set is a file including the information such as a potential of an input signal to be inputted in an input terminal of the semiconductor integrated circuit and timing of change of the potential or the like and this file is formed by means of directly describing the test pattern by the designer or outputting the test pattern by an automatic generation program of the test pattern or the like.

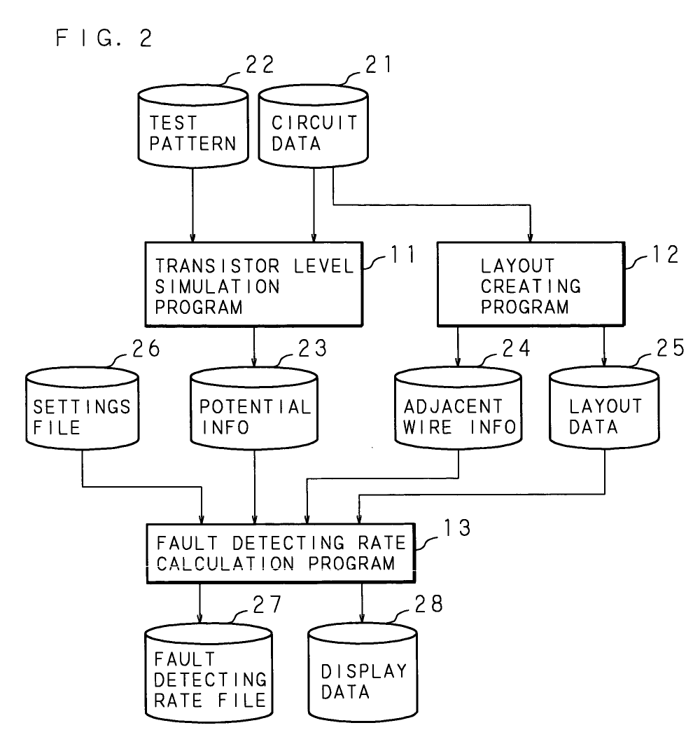

FIG. 2 is a pattern diagram showing a mutual relation between a program and data, which are recorded in the hard disk 6. The transistor simulation program 11 is an analogue simulator in which the simulation of semiconductor integrated circuit is operated at the transistor level. The transistor simulation program 11 reads the circuit data 21 and the test pattern 22; carries out simulation of the circuit data 21 in accordance with the test pattern 22; and outputs the potential information 23 of each line of the semiconductor integrated circuit described in the circuit data 21 as a file.

The layout creating program 12 is a soft ware to create a layout on the basis of the circuit designed by the designer. When the circuit is a digital circuit, the layout creating program 12 automatically arranges the line while reading the circuit data 21 and outputs the layout data 25 including the arrangement information of a gate element and the line. In addition, when the circuit is an analog circuit, the designer of the semiconductor integrated circuit or the layout designer creates a layout by hand on the basis of the circuit diagram and outputs the layout data 25. Extracting a set of the adjacent lines from the layout of the semiconductor integrated circuit formed by the automatic means or the manual means or both of them, the layout creating program 12 can output it to a file as the adjacent line information 24.

The fault detection rate calculation program 13 reads the potential information 23 outputted from the transistor level simulation program 11 and the adjacent line information 24 outputted from the layout creating program 12, and calculates the detection rate presenting how much the test pattern 22 can detect a fault of short-out between the adjacent lines in the semiconductor integrated circuit which is described in the circuit data 21. The fault detection rate calculation program 13 outputs the calculation result to a fault detection rate file 27 as a text file. The fault detection rate calculation program 13 reads a setting file 26, which is a text file having setting of the conditions of calculation described by the designer, upon calculation of the detection rate and calculates the fault detection rate in accordance with the read setting. In the setting file 26, a determination reference potential difference which is a determination reference of a potential difference between the adjacent lines and setting of timing for carrying out measurement of a current in an IDDQ test in a test time when a test is done by the test pattern 22 or the like are described.

The fault detection rate calculation program 13 can create the data for display 28 in order to display the line of which fault can be detected and the line of which fault cannot be detected by color coding with different colors respectively with emphasis on the display part 4. The fault detection rate calculation program 13 can read the layout data 25 outputted by the layout creating program 12 upon creation of the data for display 28, obtains the position information of each line from the layout data 25, and relates the position information of each line and the calculation result of the fault detection rate, whereby the fault detection rate calculation program 13 creates the data for display 28. The data for display 28 only has the color data for display with emphasis and the displayed position of each color data. In order to display with emphasis on the basis of the data for display 28, reading the layout data 25 and the data for display 28, the layout creating program 12 can display two data being superimposed each other.

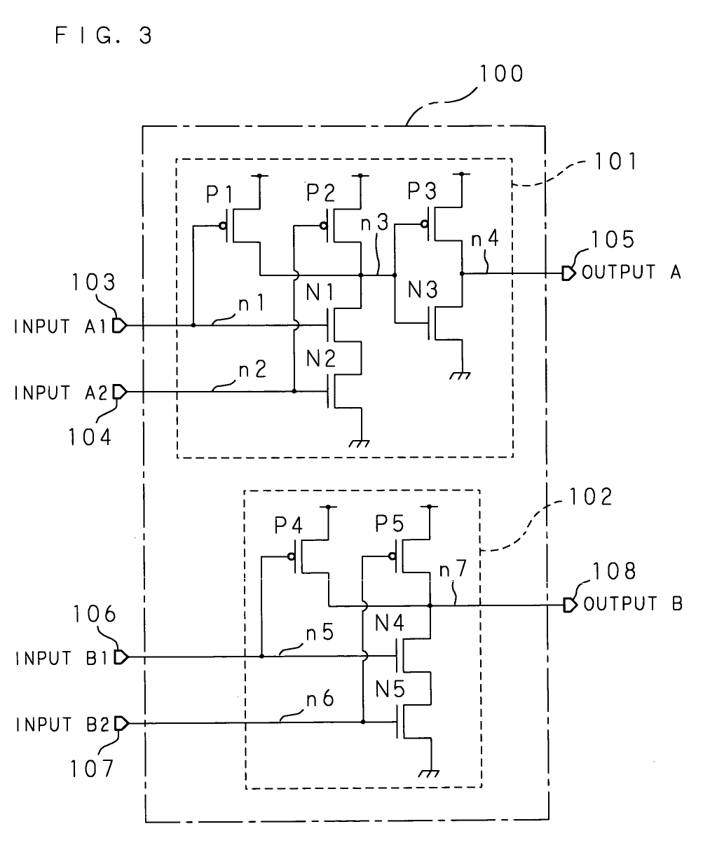

FIG. 3 is a circuit diagram showing a circuit example of a semiconductor integrated circuit. A semiconductor integrated circuit 100 illustrated in the present example is configured by a simple structure only provided with an AND element 101 and a NAND element 102. The semiconductor integrated circuit 100 is provided with an input A1 terminal 103, an input A2 terminal 104, an input B1 terminal 106, and an input B2 terminal 107 as an input terminal and further, the semiconductor integrated circuit 100 is provided with an output A terminal 105 and an output B terminal 108. Then, providing the AND calculation to two signals inputted from the input A1 terminal 103 and the input A2 terminal 104, these two signals are outputted from the output A terminal 105, and providing the NAND calculation to two signals inputted from the input B1 terminal 106 and the input B2 terminal 107, these two signals are outputted from the output B terminal 108.

The AND element 101 has three P channel-type MOS transistors (hereinafter, referred to as a PMOS transistor) P1, P2, and P3, and three N channel-type MOS transistors (hereinafter, referred to as a NMOS transistor) N1, N2, and N3; forms a NAND circuit by the PMOS transistors P1 and P2 and the NMOS transistors N1 and N2; forms an inverter circuit by the PMOS transistor P3 and the NMOS transistor N3; and inverts the output of the NAND circuit by an inverter circuit; whereby the AND element 101 carries out the AND calculation.

In other words, the input A1 terminal 103, a gate of the PMOS transistor P1, and a gate of the NMOS transistor N1 are connected each other via a line n1, and the input A2 terminal 104, a gate of the PMOS transistor P2, and a gate of the NMOS transistor N2 are connected each other via a line n2. Sources of the PMOS transistors P1 and P2 are connected to a power supply potential and drains thereof are connected to a line n3. The NMOS transistors N1 and N2 are connected in serial between a line n3 and a ground potential. The PMOS transistor P3 and the NMOS transistor N3 are connected in serial between the power supply potential and the ground potential and the line n3 is connected to the gates of the both transistors. In addition, the drains of the PMOS transistor P3 and the NMOS transistor N3 are connected to the output A terminal 105 via the line n4.

The NAND element 102 has the PMOS transistors P4 and P5 and the NMOS transistors N4 and N5, respectively. The input B1 terminal 106, the gate of the PMOS transistor P4, and the gate of the NMOS transistor N4 are connected each other via a line n5, and the input B2 terminal 107, the gate of the PMOS transistor P5, and the gate of the NMOS transistor N5 are connected each other via a line n6. The sources of the PMOS transistors P4 and P5 are connected to the power supply potential and the drains thereof are connected to a line n7. The NMOS transistors N4 and N5 are connected in serried between the line n7 and the ground potential, and the line n7 is connected to the output B terminal 108.

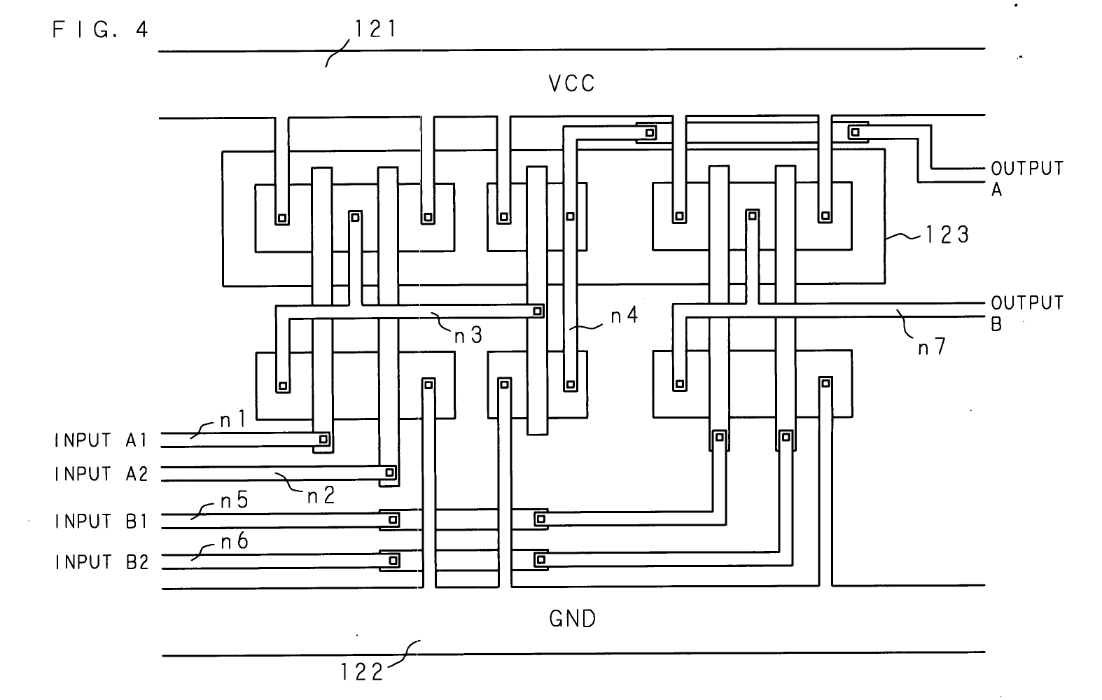

FIG. 4 is a pattern diagram showing a layout example of the semiconductor integrated circuit 100. According to the present example, each transistor and each line are formed on a P-type substrate, and a line is one-layered metal line made of aluminum. However, on a part where the lines intersect with each other, the lines made of polysilicon, which is the same material as that configuring the gate of the transistor, is used.

On the P-type substrate, an N well area 123 of an approximate rectangular shape is formed, and in the N well area 123, five PMOS transistors are formed. Along one long side part of the N well area 123, a wide power supply line 121 is arranged and is connected to the source of each PMOS transistor. At the outside from other long side part of the N well area 123, five NMOS transistors are formed so as to face five NMOS transistors. In addition, a wide GND line 122 which is approximately identical with the power supply line 121 is arranged approximately in parallel with the power supply line, and on the area between the power supply line 121 and the GND line 122, five PMOS transistors, five NMOS transistors, and the lines connecting them are formed.

According to the present layout example, there are seven sets of the adjacent lines among the lines to connect the input and output terminals to each transistor.

Namely,

the line n1-the line n2

the line n1-the line n3

the line n2-the line n5

the line n3-the line n4

the line n4-the line n7

the line n5-the line n6

the line n5-the line n7

However, it is assumed that the power supply line 121 and the GND line 122 are not considered.

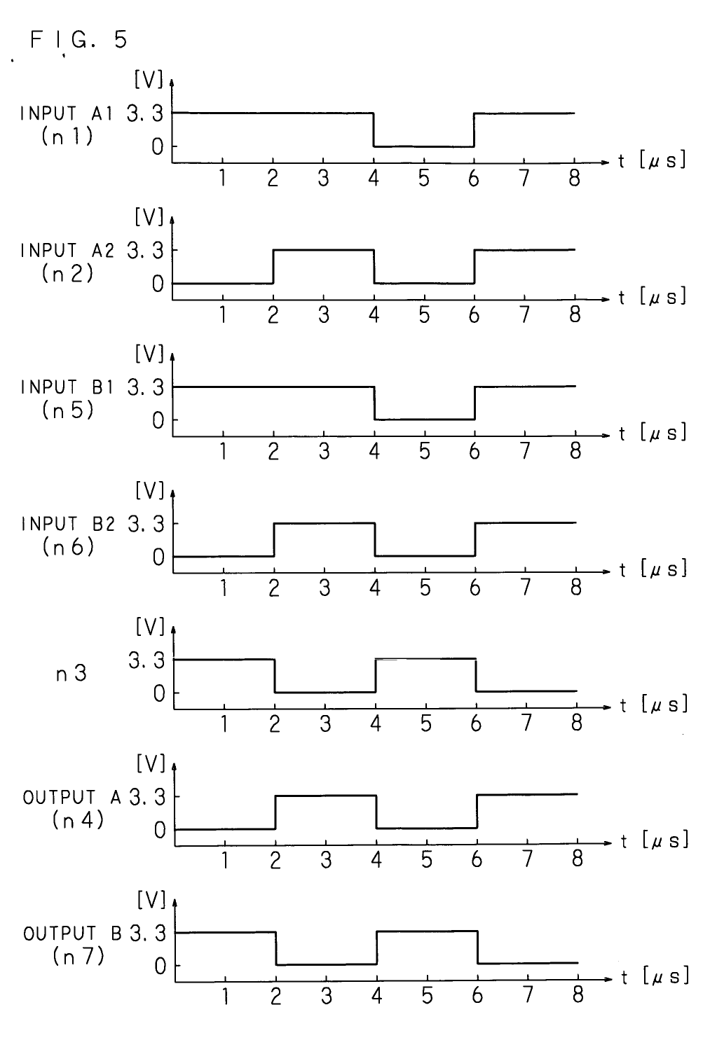

FIG. 5 is a waveform view showing a potential of each line when the test pattern 22 is inputted in the semiconductor integrated circuit 100. Further, it is assumed that a voltage of 3.3 V is supplied to the semiconductor integrated circuit 100 as a power supply. Input signals to be inputted in the input A1 terminal 103, the input A2 terminal 104, the input B1 terminal 106, and the input B2 terminal 107 are changed at a cycle of 2 μs, and their minimum potential is 0V and their maximum potential is 3.3V. For example, the input signal to be inputted in the input A2 terminal 104 is 0V between 0 μs to 2 μs, it is 3.3V between 2 μs to 4 μs, it is 0V between 4 μs to 6 μs, and it is 3.3V between 6 μs to 8 μs, respectively.

In this case, the potential of the line n3 becomes a waveform that the NAND calculation processing is provided to a signal inputted in the input A1 terminal 103 and the input A2 terminal 104, and the potential of the output A terminal 105 becomes a waveform that the waveform of the line n3 is reversed. In addition, the potential of the output B terminal 108 becomes a waveform that the NAND calculation processing is provided to a signal inputted in the input B1 terminal 106 and the input B2 terminal 107.

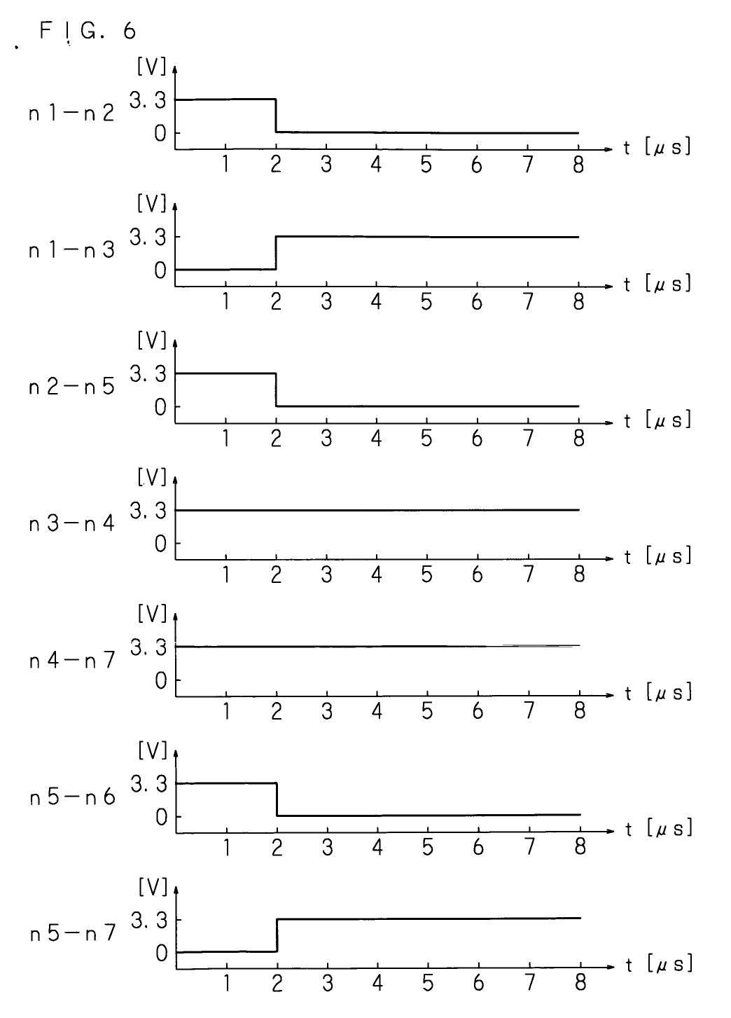

FIG. 6 is a waveform view showing a potential difference between the adjacent lines when the test pattern 22 is inputted in the semiconductor integrated circuit 100. For example, the potential difference between the line n1 and the line n2 is 3.3V between 0 μs to 2 μs, and it is 0V between 2 μs to 8 μs. In addition, the potential difference between the line n5 and the line n7 is 0V between 0 μs to 2 μs, and it is 3.3V between 2 μs to 8 μs.

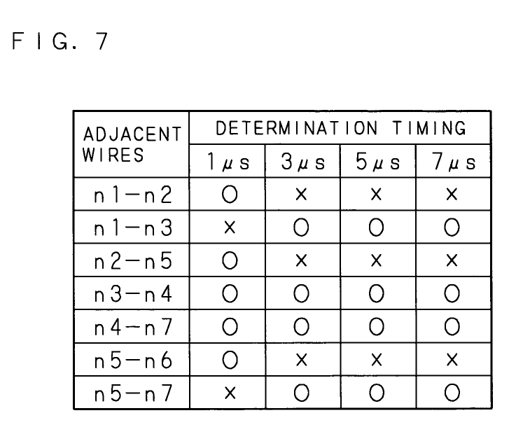

FIG. 7 is a chart showing a determination result showing if a fault due to short-out of the adjacent lines of the semiconductor integrated circuit 100 can be detected or not. However, it is assumed that the designer sets 3.0V as a reference potential of determination. In addition, as timing for determination, there are four timings of 1 μs, 3 μs, 5 μs, and 7 μs in the test pattern and in FIG. 7, a “O” or a “X” represents if the fault can be detected at each timing or not. The “O” represents the case that the fault can be detected, namely, the case that the potential difference between the lines is not less than 3.0V of the reference potential difference and the “X” represents the case that the fault cannot be detected, namely, the case that the potential difference between the lines is less than 3.0V of the reference potential difference.

As shown in FIG. 7, when determination is carried out at timing of 1 μs, short-out of the line n1 and the line n3 and short-out of the line n5 and the line n7 cannot be detected. In addition, when determination is carried out at timing of 3 μs, short-out of the line n1 and the line n2, short-out of the line n2 and the line n5, and short-out of the line n5 and the line n6 cannot be detected. Also in the case that determination is carried out at timings of 5 μs and 7 μs, the same as the case that determination is carried out at timing of 3 μs applies.

Therefore, when timing of determination is set at 1 μs in the setting file 26, the fault detection rate is allowed to be calculated as 5/7=71%. In addition, when timing of determination is set at 3 μs, the fault detection rate is allowed to be calculated as 4/7=57%. Further, since the fault can be detected in the all combinations when the designer sets two, namely, 1 μs and 3 μs as timing of determination, the fault detection rate becomes 100%. From these results, there is no need to carry out determination of the fault of short-out of the line at 5 μs and 7 μs, so that, deleting the test pattern between 4 μs to 8 μs, the test time can be shortened.

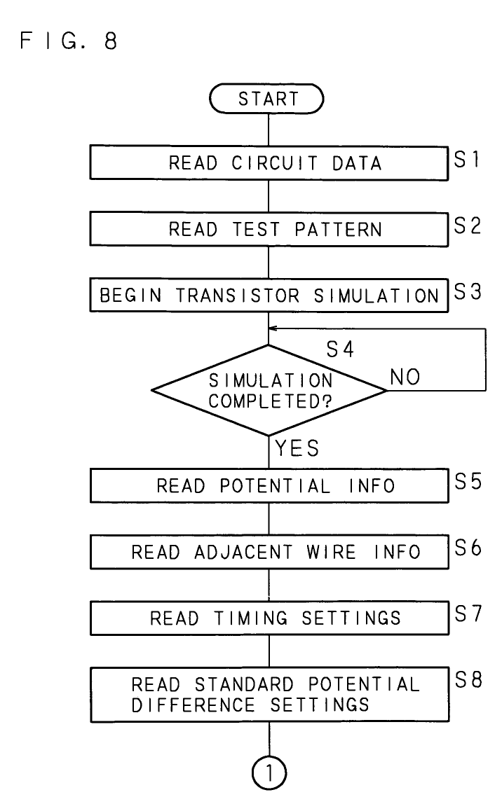

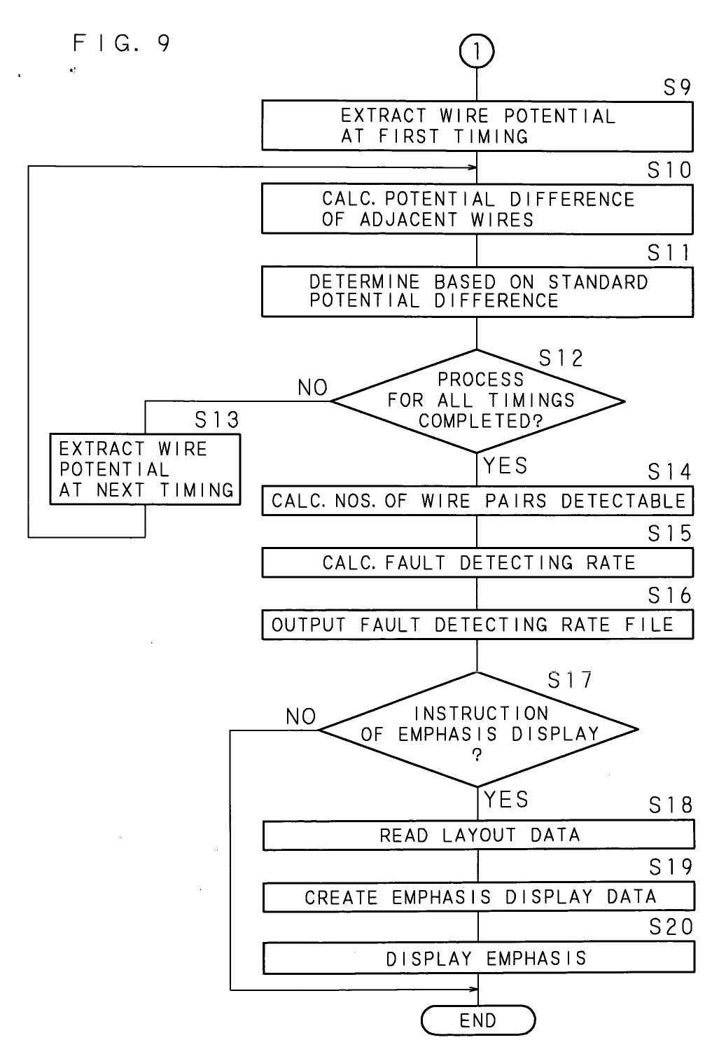

Each of FIG. 8 and FIG. 9 is a flow chart showing a processing order of a program for calculating a fault detection rate 10 according to the present invention. At first, the program 10 reads the circuit data 21 of the semiconductor integrated circuit created by the designer (step S1) and reads the test pattern 22 (step S2). After reading, the program 10 may start simulation of a transistor level due to the circuit data 21 and the test pattern 22 read by activating the transistor level simulation program 11 (step S3). After that, checking if the simulation of the transistor level is completed or not (step S4), if the simulation is not completed (S4: NO), the program 10 may stand by till the simulation is completed.

When the simulation of the transistor level is completed (S4: YES), the program 10 may read the potential information 23 of each line of the semiconductor integrated circuit as a simulation result (step S5) and may read the adjacent line information 24 which is the information with respect to the adjacent lines of the semiconductor integrated circuit and is outputted by the layout creating program 12 (step S6). Further, the program 10 may read timing setting set by the designer in the setting file 26 which is the timing of current measurement of the IDDQ test (step S7) and may read the reference potential difference setting which is the determination reference of the potential difference between the adjacent lines from the setting file 26 (step S8).

Extracting the potential of each line about the first timing from the potential information 23 on the basis of the read setting timing (step S9), the program 10 may calculate the potential difference between the adjacent lines on the basis of the adjacent line information 24 which is read in the step S6 (step S10). Next, comparing the calculated potential difference with the reference potential difference which is read in the step S8, the program 10 may determine if the potential difference not less than the reference potential is generated between the adjacent lines or not (step S11). After this determination has been done with respect to the all adjacent lines, checking if the determination processing has been completed about the set all timings (step S12), when the determination processing has not been completed about the all timings (S12: NO), extracting the potential of each line about the next timing from the potential information 23 (step S13) and returning to the step S10, the program 10 may continue to calculate the potential difference between the adjacent lines, compare the calculated potential difference with the reference potential difference, and determine if the potential difference not less than the reference potential is generated between the adjacent lines or not.

When the processing has been completed with respect to the all timings (S12: YES), the number of a set of the lines having a detectable short-out between the lines from the test pattern, namely, the number of a set of the lines determined that a potential difference larger the reference potential difference is generated between the lines in the step S11 is calculated (step S14). From the calculating result of step S14, calculating the number of sets of the lines which can be calculated against the number of sets of the all adjacent lines as a fault detection rate of the semiconductor integrated circuit (step S15), the program 10 may output the calculated fault detection rate as the fault detection rate file 27.

Consequently, the program 10 may check if there has been an instruction from the designer to display the line of which fault of short-out between the lines can be detected and the line of which fault of short-out between the lines cannot be detected with emphasis or not (step S17). For example, if the display with emphasis is made or not may be described in the setting file 26 in advance by the designer and this may be read in step S17, or if the display with emphasis is made or not may be designated by the designer upon execution of the layout creating program 12, or other method may be available. If there is an instruction to carry out the display with emphasis (S17: YES), reading the layout data 25 created by the layout creating program 12 (step S18) and obtaining the position information of the line to be displayed with emphasis from the layout data 25, the program 10 may create and output the data for display 28 composed of color data for display with emphasis and a display position of the color data (step S19). After that, activating the layout creating program 12, causing the layout creating program 12 to read the layout data 25 and the data for display 28, the program 10 may display the lines with emphasis by using a display function of the layout owned by the layout creating program 12 (step S20).

When the designer does not instruct to display the lines with emphasis in the step S17 (S17: NO) and step S20, and after the lines are displayed with emphasis by using the layout creating program 12, the processing of the fault detection rate calculation program 13 is terminated.

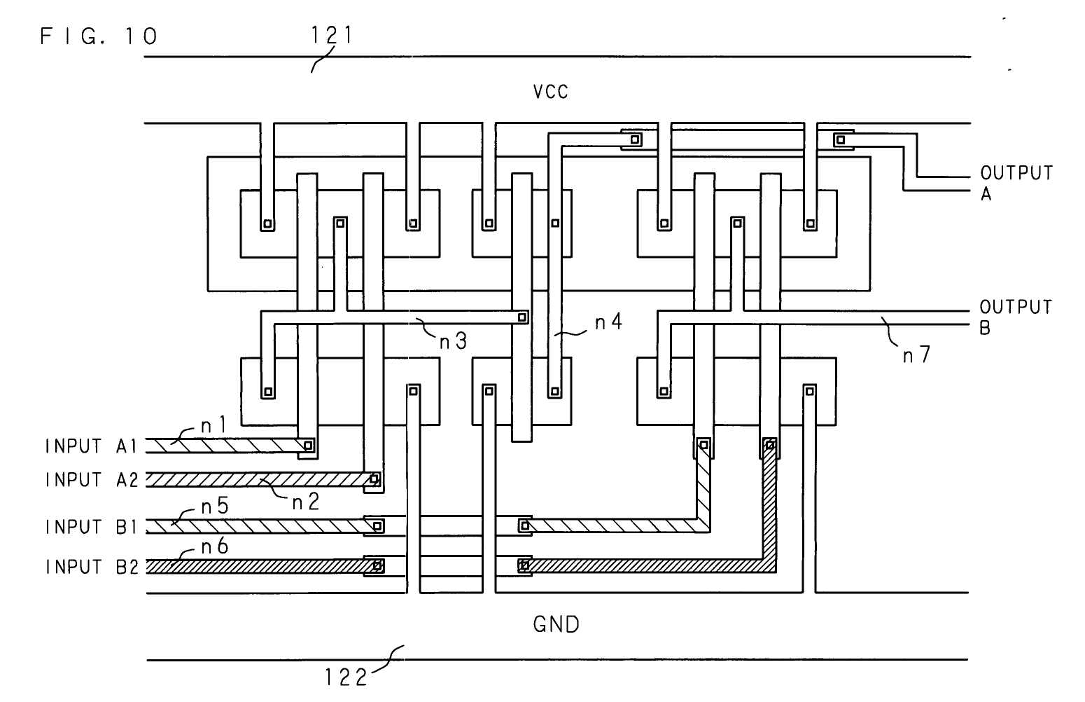

FIG. 10 is a pattern view showing an emphasis display example of the layout of the semiconductor integrated circuit 100 and this is a display example when determination is carried out only in 3 μs in the test pattern. As shown in FIG. 7, short-out of the line n1 with the adjacent line n2 cannot be detected but short-out of the line n1 with the adjacent line n3 can be detected, so that short-out of the line n1 with the adjacent lines can be detected for ½. In the same way, if the fault of short-out between some lines with respect to the number of the adjacent lines can be detected or not in each line is shown as follows:

| | |
|---|---|
| line n1 | 1/2 |
| line n2 | 0/2 |
| line n3 | 2/2 |
| line n4 | 2/2 |
| line n5 | 1/3 |
| line n6 | 0/1 |
| line n7 | 2/2 |

By displaying the lines by color coding with plural colors in accordance with this rate (in FIG. 10, color coding is carried out by providing different kinds of hatching to the line), the display which the designer can check more easily can be realized. For example, color-coding is carried out in the order from a color from one that can be detected with a higher rate to one that can be detected with a lower rate, namely, colorless, pink, red, and deep red.

According to the fault detection rate calculation apparatus configured as described above, it is possible to easily calculate a rate capable of detecting a fault with respect to short-out between the adjacent lines in the semiconductor integrated circuit by determining if the fault detection rate calculation apparatus can detect the fault or not on the basis of the potential information 23 of each line obtained from the transistor level simulation program 11 and the adjacent line information 24 obtained from the layout creating program 12 in accordance with if the potential difference between the adjacent lines is larger than the reference potential difference or not. In addition, by causing the designer to set the setting file 26 so as to carry out determination at predetermined timing in the test pattern 22, the timing of determination can be set in accordance with timing of current measurement of the IDDQ test and the fault detection rate calculation apparatus can calculate a more reliable detection rate. Further, by displaying if short-out between the lines can be detected or not by displaying the line by color coding with different colors on the layout with emphasis, the line having short-out between the lines which cannot be detected by the designer can be reliably checked. Further, by carrying out simulation of the semiconductor integrated circuit at the transistor level, it is also possible to determine if short-out between the lines in the gate element configuring the circuit can be also detected or not.

Further, according to the present embodiment, as the adjacent lines, the power supply line and the GND line are not considered; however, the present embodiment may be configured so as to determine if short-out between the lines including the power supply line and the GND line can be detected or not. In addition, as the information about the adjacent lines, the configuration to output the adjacent line information 24 by the layout creating program 12 is indicated; however, not limited to this, the configuration that the fault detection rate calculation program 13 reads the layout data 25 and creates the layout may be also available.

In addition, the circuit diagram of the semiconductor integrated circuit 100 shown in FIG. 3 is merely an example. The present embodiment is not limited to this and the semiconductor integrated circuit 100 may have the line which is the power supply potential or the potential other than the GND potential being provided with a reference voltage output circuit or an analog circuit such as an amplification circuit due to an operation amplifier or the like. In addition, the layout shown in FIG. 4 is merely an example and the present embodiment is not limited to this. For example, the present embodiment may have a metal line of two and more layers. In this case, the present embodiment may be configured so as to calculate if short-out of the vertically adjacent lines can be detected or not.

The configuration to calculate the fault detection rate from the result of the simulation of the transistor level is shown; however, the present embodiment is not limited to this and the configuration to calculate the fault detection rate on the basis of the result of the simulation of the gate level may be also available. In addition, in the case of the semiconductor integrated circuit that the digital circuit and the analog circuit are mixed, the present embodiment may be configured in such a manner that, for the digital circuit, simulation of the gate level is carried out, and for the analog circuit, simulation of the transistor level is carried out. In addition, the configuration to display the layout of the semiconductor integrated circuit with emphasis is indicated as shown in FIG. 10; however, not limited to this, the present embodiment may be configured so as to display the line of the semiconductor integrated circuit with emphasis as shown in FIG. 3. Further, in FIG. 1, the configuration that the transistor simulation program 11, the layout creating program 12, and the fault detection rate calculation program 13 are provided in one computer; however, not limited to this, the configuration that each program is provided in other computer and each program performs communication via the communication interface 5 of the computer may be available and further, the configuration to exchange the output result of each program via a recording medium such as a CD or a DVD may be also available.

As this invention may be embodied in several forms without departing from the spirit of essential characteristics thereof, the present embodiment is therefore illustrative and not restrictive, since the scope of the invention is defined by the appended claims rather than by description preceding them, and all changes that fall within metes and bounds of the claims, or equivalence of such metes and bounds thereof are therefore intended to be embraced by the claims.

What is claimed is:

1. A detection rate calculation method of a test pattern for calculating a detection rate of a fault of an integrated circuit detected by a test pattern in which an input voltage pattern data for testing the integrated circuit is set, the method comprising steps of:
extracting, based on arrangement information with respect to wires of the integrated circuit, combinations of a pair of adjacent wires;
calculating a potential of each wire when the test pattern is inputted in the integrated circuit;
determining whether or not a potential difference between each combination of a pair of the adjacent wires is larger than a predetermined potential difference; and
calculating the detection rate in accordance with a determination result on the potential difference.

2. The detection rate calculation method according to claim 1, further comprising a step of
obtaining information with respect to timing for determining on the potential difference,
wherein determination on the potential difference is carried out at the timing in the test pattern.

3. The detection rate calculation method according to claim 1, wherein, in the step of calculating the detection rate,
in accordance with the determination result on the potential difference, it is determined whether or not the fault of the integrated circuit is detected, and
in accordance with a determination result on the fault of the integrated circuit, the detection rate is calculated.

4. The detection rate calculation method according to claim 1, wherein, in the step of calculating the detection rate,
a rate of a number of the combinations of a pair of adjacent wires, between each of which potential difference is determined to be larger than a predetermined potential difference, with respect to a total number of the combinations of a pair of adjacent wires is calculated as the detection rate.

5. A memory product which is readable by a computer and stores a computer program causing the computer to calculate a detection rate of a fault of an integrated circuit detected by a test pattern in which an input voltage pattern data for testing the integrated circuit is set, the computer program comprising steps of:
causing the computer to determine whether or not a potential difference between a combination of a pair of adjacent wires of the integrated circuit is larger than a predetermined potential difference; and
causing the computer to calculate the detection rate in accordance with a determination result on the potential difference.

6. The memory product according to claim 5, wherein the computer program further comprises a step of
causing the computer to obtain information with respect to the predetermined potential difference, and
in the step of causing the computer to determine, the determination is carried out in accordance with the obtained information.

7. The memory product according to claim 5, wherein the computer program further comprises a step of
causing the computer to obtain information with respect to timing for determining on the potential difference, and
in the step of causing the computer to determine, the determination is carried out at the timing in the test pattern.

8. The memory product according to claim 5, wherein, in the step of causing the computer to calculate the detection rate,
in accordance with the determination result on the potential difference, it is determined whether or not the fault of the integrated circuit is detected; and
in accordance with a determination result on the fault of the integrated circuit, the detection rate is calculated.

9. The memory product according to claim 5, wherein, in the step of causing the computer to calculate the detection rate,
a rate of an accumulated number of each combination of a pair of adjacent wires, between each combination of which potential difference is determined to be larger than a predetermined potential difference, with respect to a totally accumulated number of each combination of a pair of adjacent lines is calculated as the detection rate.

10. The memory product according to claim 5, wherein the computer program further comprises a step of
causing the computer, on the basis of the determination result on the potential difference, to create display data to display the determination result with emphasis on a position of each wire in accordance with arrangement information with respect to wires.

11. The memory product according to claim 10, wherein, in the step of causing the computer to create the display data, in accordance with the determination result on potential difference, a color mark is set at a position of each wire.

12. A detection rate calculation apparatus of a test pattern for calculating a detection rate of a fault of an integrated circuit detected by a test pattern in which an input voltage pattern data for testing the integrated circuit is set, comprising a controller capable of performing operations of:
determining whether or not a potential difference between a combination of a pair of adjacent wires of the integrated circuit is larger than a predetermined potential difference; and
calculating the detection rate in accordance with a result of determination on the potential difference.

13. The detection rate calculation apparatus according to claim 12, wherein the controller is further capable of performing an operation of
obtaining information with respect to timing for determining on the potential difference, and
in the operation of determining on the potential difference, the determination is carried out at the timing in the test pattern.

14. The detection rate calculation apparatus according to claim 12, wherein, in the operation of calculating the detection rate,
in accordance with the result of the determination on the potential, it is determined whether or not the fault of the integrated circuit is detected; and
in accordance with a determination result on the fault of the integrated circuit, the detection rate is calculated.

15. The detection rate calculation apparatus according to claim 12, wherein, in the operation of calculating the detection rate,
a rate of an accumulated number of each combination of a pair of adjacent wires, between each combination of which potential difference is determined to be larger than a predetermined potential difference, with respect to a totally accumulated number of each combination of a pair of adjacent wires is calculated as the detection rate.

16. The detection rate calculation apparatus according to claim 12, wherein
the controller is further capable of performing operations of:
obtaining arrangement information with respect to wires of the integrated circuit; and
creating display data, based on the determination result, to display the determination result with emphasis on a position of each wire in accordance with the arrangement information, and
the display part displays an image on the basis of the data for display.

17. The detection rate calculation apparatus according to claim 12, wherein the controller is further capable of performing operations of:
executing a transistor level simulation of the integrated circuit; and
obtaining information with respect to a potential of each wire.

18. A detection rate calculation apparatus of a test pattern for calculating a detection rate of a fault of an integrated circuit detected by a test pattern in which an input voltage pattern data for testing the integrated circuit is set, comprising:
wire information obtaining means for obtaining information with respect to combinations of a pair of the adjacent wires, extracted from arrangement information with respect to wires of the integrated circuit;
potential information obtaining means for obtaining the information with respect to a potential of each wire when the test pattern is inputted in the integrated circuit;
determining means for determining whether or not a potential difference between each combination of a pair of the adjacent wires is larger than a predetermined potential difference; and
calculating means for calculating the detection rate in accordance with a determination result of the determining means.

19. The detection rate calculation apparatus according to claim 18, further comprising
timing information obtaining means for obtaining information with respect to a timing for determining on the potential difference,
wherein the determining means carries out determination at the timing in the test pattern.

20. The detection rate calculation apparatus according to claim 18, wherein
the determining means further determines whether or not the fault of the integrated circuit is detected, in accordance with the determination result on the potential difference, and
the calculating means calculates the detection rate, in accordance with a determination result on the detection of the fault of the integrated circuit.

21. The detection rate calculation apparatus according to claim 18, wherein
the calculating means calculates a rate of an accumulated number of each combination of a pair of the adjacent wires, between each combination of which potential difference is determined to be larger than a predetermined potential difference, with respect to a totally accumulated number of each combination of a pair of the adjacent wires is calculated as the detection rate.

22. The detection rate calculation apparatus according to claim 18, further comprising:
arrangement information obtaining means for obtaining arrangement information with respect to the wires of the integrated circuit;
creating means for creating display data, based on the determination result, for displaying the determination result with emphasis on a position of each wire in accordance with the arrangement information; and
display processing means of carrying out processing with relate to the display data.

23. The detection rate calculation apparatus according to claim 18, wherein
the potential information obtaining means executes a transistor level simulation of the integrated circuit and obtains information with respect to a potential of each wire.

24. A memory product which is readable by a computer and stores a computer program causing the computer to calculate a detection rate of a fault of an integrated circuit detected by a test pattern in which an input voltage pattern data for testing the integrated circuit is set, the computer program comprising steps of:
causing the computer to obtain information with respect to combinations of adjacent wires of the integrated circuit extracted from arrangement information of the integrated circuit;
causing the computer to obtain information with respect to a potential of each wire when the test pattern is inputted in the integrated circuit;
causing the computer to determine whether or not a potential difference between each combination of the adjacent wires is larger than a predetermined potential difference; and
causing the computer to calculate the detection rate in accordance with a determination result on the potential difference.

25. A detection rate calculation apparatus of a test pattern for calculating a detection rate of a fault of an integrated circuit detected by a test pattern in which an input voltage pattern data for testing the integrated circuit is set, comprising a controller capable of performing operations of:
obtaining information with respect to combinations of adjacent wires extracted from arrangement information with respect to wires of the integrated circuit;
obtaining information with respect to a potential of each wire when the test pattern is inputted in the integrated circuit;
determining whether or not a potential difference between each combination of the adjacent wire is larger than a predetermined potential difference; and
in accordance with the determination result, calculating the detection rate.
